(19) United States
(12) Patent Application Publication
(10) Pub. No.: US 2016/0150683 A1
(43) Pub. Date: May 26, 2016

(54) DISPLAY ENCLOSURE

(71) Applicant: CIIL TECHNOLOGIES, LLC, Aurora, IL (US)

(72) Inventors: Steve Sagerian, Plainfield, IL (US); John Michael Gillespie, Green Oaks, IL (US); Michael Campagna, Plainfield, IL (US); Justin Myers, Plainfield, IL (US)

(73) Assignee: CIIL Technologies, LLC, Aurora, IL (US)

(21) Appl. No.: 14/897,282

(22) PCT Filed: Jun. 12, 2014
(86) PCT No.: PCT/US14/42095

§ 371 Date: Dec. 10, 2015

Related U.S. Application Data
(60) Provisional application No. 61/834,303, filed on Jun. 12, 2013.

(51) Int. Cl. H05K 7/20; F25B 21/04

(52) U.S. Cl. CPC H05K 7/20963; H05K 7/20; F25B 21/04

(57) ABSTRACT

A display enclosure having a thermal management system may include a display enclosure sized and configured to receive a display device in an interior of the display enclosure. The display enclosure may include a thermoelectric module having a first portion and a second portion. The first portion is positioned within the interior of the display enclosure and may heat or cool the interior of the display enclosure. The second portion is coupled to a portion of the display enclosure exposed to an external environment to dissipate heat or cool to the external environment. A thermal controller electrically may be coupled to the thermoelectric module and operable to control the heating or cooling of the first portion of thermoelectric module.

### CROSS-REFERENCE TO RELATED APPLICATION

The present application claims the benefit of and priority to U.S. Provisional Patent Application Ser. No. 61/834,303, filed Jun. 12, 2013, which is incorporated herein by reference in its entirety.

### FIELD OF THE INVENTION

The present invention relates generally to structures for enclosing display devices. More particularly, the present invention relates to enclosures for heating and/or cooling display devices and/or the interior of the display enclosure.

### BACKGROUND

This section is intended to provide a background or context to the invention that is recited in the claims. The description herein may include concepts that could be pursued, but are not necessarily ones that have been previously conceived or pursued. Therefore, unless otherwise indicated herein, what is described in this section is not prior art to the description and claims in this application and is not admitted to be prior art by inclusion in this section.

In recent years, flat panel televisions have become enormously popular in both commercial and residential sectors. As the prices for plasma and liquid crystal display (LCD) flat panel displays have continued to fall, and the quality for the same devices have improved, more and more businesses and individuals have purchased such devices for both home and business purposes.

The advantages of flat panel displays has also led to expanded application and placement of display devices, including locating display devices in new and challenging and environments. For example, display devices might be located outdoors in various residential and commercial settings for entertainment or marketing purposes, potentially exposing the display device to damaging rain, snow, debris, and other elements. Display devices might also be located in indoor environments such as restrooms, kitchens, and industrial settings for various entertainment, marketing, and informational purposes. As with outdoor applications, liquids and other potential contaminants may be near or come into contact with the mounted display device, potentially damaging or degrading the performance of the display device. It is desirable to protect the display device, which is often quite expensive, from exposure to environmental and other potential contaminants. Accordingly, various environmental enclosures have been developed that are intended to protect a display device from the elements and other containments to permit locating such displays outdoors and in other potentially inhospitable environments.

When the display device is within the environmental enclosure, the temperature within the enclosure may vary depending on the environment. For example, in an outdoor environment with cold temperatures, the interior temperature within the enclosure may be similarly cold, which may affect the operation of the display device (e.g, dimming the screen of the display device, freezing a liquid crystal display, etc.). Similarly, in an outdoor environment with hot temperatures, the interior temperature within the enclosure may be similarly hot, which may affect the operation of the display device (e.g., overheating electronics components within the display device, etc.).

### SUMMARY

Various embodiments comprise enclosed display device systems with a heating and/or cooling system for display devices such as a CRT, DLP, LCD, LED or plasma display device. In some implementations, these enclosure systems having a heating and/or cooling system may be used for CRT, DLP, or other non-low profile display devices. The various enclosure systems are substantially sealed and weatherproofed, thereby preventing ingress of liquids, such as precipitation, that may occur at an outdoor viewing location. The enclosure systems according to various embodiments provide a heating and/or cooling system for thermal management of the interior of the display enclosure system and of the enclosed display device. Modern flat panel display devices typically generate heat while in use. In some instances, the heat load generated can be substantial under various circumstances. Consequently, the temperature within an enclosure can rapidly rise above the thermal operating range of the display device unless mitigated. Thermal conditions within the enclosure may be exasperated by ambient conditions, for example, high ambient temperatures and/or a high solar load on the display enclosure. Additionally, under low ambient temperatures it may be necessary to generate additional heat within the enclosure when the display device is on or off in order to protect the display device and/or maintain sufficient operating temperature within the enclosure. Accordingly, the enclosure systems may include a thermoelectric heating and/or cooling module to control the temperature within the enclosure.

In one set of embodiments, a display enclosure with a temperature control system main include a display enclosure having an interior. The interior is sized and configured to receive a display device therein. The display enclosure also includes a thermoelectric module having a first portion and a second portion. The first portion is positioned within the interior of the display enclosure. The second portion is coupled to a portion of the display enclosure exposed to an external environment. The display enclosure further includes a thermal controller electrically coupled to the thermoelectric module and operable to control heating or cooling of the first portion of the thermoelectric module.

In another set of embodiments, a display enclosure with a temperature control system includes a display enclosure having an interior sized and configured to receive a display device therein. The display enclosure includes a thermoelectric module having a first portion and a second portion. The first portion is positioned within the interior of the display enclosure and the second portion is coupled to a portion of the display enclosure exposed to an outdoor environment. The display enclosure also includes a temperature sensor positioned within the interior of the display enclosure. The display enclosure further includes a thermal controller electrically coupled to the thermoelectric module and the temperature sensor. The thermal controller is operable to receive a first signal indicative of a temperature of the interior of the display enclosure output from the temperature sensor. The thermal controller further being operable to control heating or cooling of the first portion of the thermoelectric module based, at least in part, on the first signal output from the temperature sensor.

In yet another set of embodiments, a method for controlling the internal temperature of a display enclosure includes receiving, at a thermal controller of a display enclosure, a first signal indicative of a temperature of an interior of the display enclosure. The method includes determining whether the first signal indicative of the temperature of the interior of the display enclosure is above a first temperature set point and activating a thermoelectric module to cool the interior of the display enclosure if the first signal indicative of the temperature of the interior of the display enclosure is above the first temperature set point. The method further includes deactivating the thermoelectric module when the first signal indicative of the temperature of the interior of the display enclosure is below the first temperature set point.

These and other features, together with the organization and manner of operation thereof, will become apparent from the following detailed description when taken in conjunction with the accompanying drawings, wherein like elements have like numerals throughout the several drawings described below.

### BRIEF DESCRIPTION OF THE DRAWINGS

FIG. 1 is an exploded view of an enclosed display device constructed in accordance with one particular embodiment;

FIG. 2 is an exploded view showing the bezel and display brackets of the enclosed display device of FIG. 1;

FIG. 3A is a perspective view of the rear cover assembly of FIG. 1, and FIG. 3B is exploded view of the rear cover assembly of FIG. 3A;

FIG. 4 is a rear perspective view of the enclosed display device of FIG. 1;

FIG. 5A is a front plan view of the front cover of the enclosed display device of FIG. 1, and FIG. 5B is a cross section showing a portion of the bezel and the front cover of the enclosed display device of FIG. 1;

FIG. 6 is a partial cross sectional view of the rear cover assembly showing a thermoelectric module coupled to the rear cover assembly;

FIG. 7 is another partial cross sectional view of the rear cover assembly showing a thermoelectric module partially embedded in the rear cover assembly;

FIG. 8 is still another partial cross sectional view of the rear cover assembly having an opening and showing a thermoelectric module having a second portion extending through the rear cover assembly;

FIG. 9 is a schematic block diagram illustrating components of the enclosed display device of FIG. 1;

FIG. 10 is a flow diagram of an example process for controlling the thermoelectric module based on temperature; and

FIG. 11 is a flow diagram of another example process for controlling the thermoelectric module based on temperature and humidity.

### DETAILED DESCRIPTION

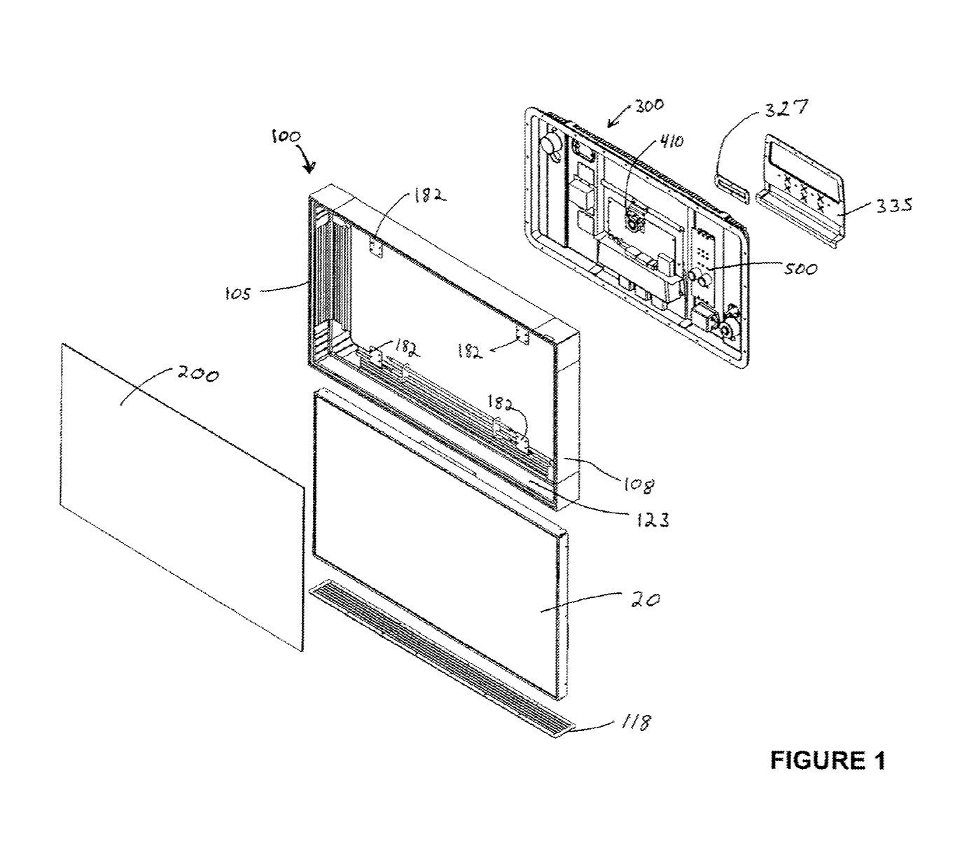

FIGS. 1-5 illustrate a display enclosure 10 constructed in accordance with one particular embodiment. The display enclosure 10 is a protective enclosure sized and configured to enclose a display device 20, such as a LCD, LED or plasma flat panel display device, within an interior of the display enclosure 10. The display enclosure 10 comprises a bezel 100 that defines a frame disposed about the periphery of the display device 20. A front cover 200, or display cover, is coupled to the bezel 100 and covers a display opening 111, or front opening, defined by the bezel 100. The front cover 200 comprises a substantially transparent material that permits viewing of the display device 20 within the display enclosure 10. The display enclosure 10 further comprises a rear cover assembly 300 coupled to the bezel 100. The rear cover assembly 300 covers a rear opening 311, opposite the display opening 111, defined by the bezel 100. The rear cover assembly 300 may include a heat sink portion and a cable entry portion 350 that permits passage of various power, video, audio, and other data carrying cables.

The display enclosure 10 is constructed so that the display device 20 may be located in an outdoor viewing environment or in other environments where the display device 20 requires or may benefit from protection from ambient conditions. Accordingly, the display enclosure 10 is constructed to resist and substantially prevent ingress of various liquids that may be encountered in the viewing location, including precipitation when the display enclosure 10 is mounted for outdoor viewing of the display device 20. In various embodiments, the display enclosure 10 is constructed to prevent ingress of rain, snow and splashing liquid. In a particular embodiment, the display enclosure 10 is constructed to prevent ingress of liquid at a submersed depth of up to five feet of water, which may correspond to a modified rating of the IP68 standard (the contents of which are incorporated herein by reference).

As described in greater detail below, the display enclosure 10 may be provided with features that enable or enhance performance and operation under various ambient conditions, while protecting the display device 20 from adverse conditions, such as liquids that may come into contact with the display enclosure 10 or varying ambient temperatures. The bezel 100, for example, may be constructed to provide the display enclosure 10 with a narrow periphery, or a low profile, that closely surrounds the display opening 111 through which the display area of the display device 20 is visible. Thus, the outer periphery of the bezel 100 defines an area and the display opening 111 defines a display opening area. In this configuration, the distance between an inner edge of the bezel 100 and the periphery of the bezel 100, the bezel thickness, is minimized. In a particular embodiment, the bezel thickness is less than about 50 mm, and in a further embodiment, the bezel thickness is less than about 25 mm. In further embodiments, the bezel thickness may fall between about 25 mm and about 50 mm.

The low profile of the bezel 100 permits the display area of the display device 20 to closely approach the periphery of the bezel 100. For example, the display opening area is maximized relative to the enclosure area. In a particular embodiment, the display opening area is at least about 85 percent of the enclosure area, and in another embodiment, the display area opening is at least about 92 percent of the enclosure area. In further embodiments, the display area opening may fall between about 85 percent and about 92 percent of the enclosure area. The above described configurations offer a clean, low profile look where the edge of the display area of the display device 20 is in proximity of the periphery of the display enclosure 10. These configurations permit, for example, a plurality of enclosures 10, each with a display device 20, to be arranged in a video wall such that the respective display devices 20 are in close proximity to one another, thereby enhancing the presentation of the image or images displayed on the display devices 20.

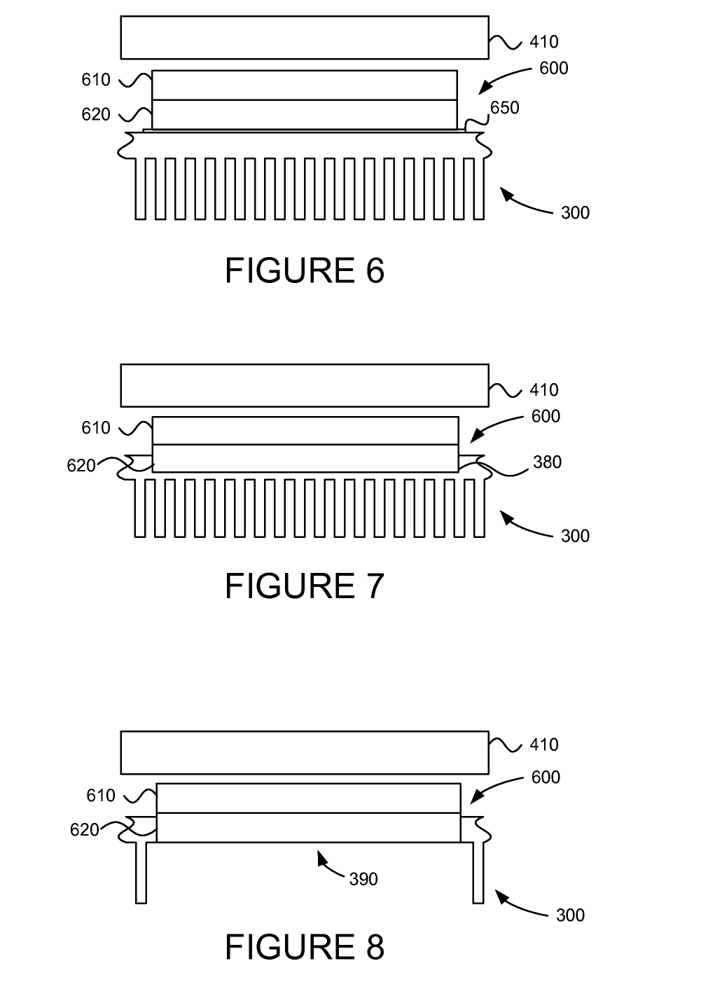

The display enclosure 10 may also include a heating and/or cooling system for thermal management of the internal temperature. Such a heating and/or cooling system may be an active system that controls the temperature within the display enclosure 10 and in maintaining an internal temperature that is within an operating range of the display device 20. Referring briefly to FIGS. 6-8, the heating and/or cooling system may include a thermoelectric module 600, and more particularly a Peltier thermoelectric module. One example of such a Peltier thermoelectric module is be a TEC1-12705 Thermoelectric Peltier Cooler available from Hebei I. T. (Shanghai) Co., Ltd. of Shanghai, China. The Peltier thermoelectric module of the present example is a silicon device having a first portion 610 and a second portion 620. The first portion 610 may be positioned within an interior of the display enclosure 10 and the second portion 620 may be coupled to a portion of the display enclosure 10, exposed to the external environment. When an electric current is applied to the thermoelectric module 600 in a first direction, the first portion 610 is cooled and the second portion 620 is heated. When the electric current is applied to the module 600 in a second direction, substantially opposite the first direction, the first portion 610 is heated and the second portion 620 is cooled. Accordingly, it may be appreciated that the internal temperature of the display enclosure 10 may be actively regulated, by heating or cooling the first portion 610, using the thermoelectric module 600. In some implementations, a plurality of thermoelectric modules 600 may be provided to form a thermoelectric module array.

In some embodiments, the first portion 610 of the thermoelectric module or modules 600 may be aligned with a portion of the display device 20 that is thermally sensitive or otherwise may benefit from thermal management. For example, the first portion 610 may be positioned within the display enclosure 10 such that the first portion 610 is substantially aligned with a location for a power supply module of the display device 20 and/or of the display enclosure 10, such as power supply 500. In other examples, the first portion 610 may be positioned such that the first portion 610 is substantially aligned with the display device 20 at other locations (e.g., near a TV tuner circuit, audio components, a processor or processing module, a computer-readable storage device, etc.) and/or other components of the display enclosure 10. In still other embodiments, the thermoelectric module or modules 600 and the first portion 610 may be arbitrarily positioned within the display enclosure 10.

In some embodiments, the second portion 620 of each thermoelectric module or modules 600 may be coupled to a rear cover assembly 300 for heat transfer to the heat sink portion of the rear cover assembly 300. For example, the thermoelectric module 600 and the rear cover assembly 300 may be coupled together (e.g., via connecting elements such as bolts, screws, latches, clamps, clips, etc. via adhesives, or otherwise) and may include a thermally conductive grease or adhesive interposed between the second portion 620 and the heat sink portion, as will be discussed in further detail in reference to FIG. 6. Thus, the second portion 620 is conductively coupled to the heat sink portion of the rear cover assembly 300. In other embodiments, the thermoelectric module 600 may be integrated or embedded in the rear cover assembly 300 (e.g., a recess may be formed in the rear cover assembly 300 for the thermoelectric module 600 to be embedded, as will be discussed in further detail in reference to FIG. 7). In yet a further configuration, the rear cover assembly 300 may include an opening for the second portion 620 to be exposed to the external environment, as will be discussed in further detail in reference to FIG. 8. In still further implementations, the second portion 620 of the thermoelectric module 600 may be associated with another portion of the display enclosure 10, such as a side of the bezel 100. The second portion 620 may be conductively coupled to a heat sink located on the side of the bezel 100 as well. In some embodiments, a plurality or an array of thermoelectric modules 600 may be positioned within the display enclosure 10. The Peltier thermoelectric module 600 and control thereof will be described in greater detail below.

The display enclosure 10 may further include various additional features that, for example, sense ambient light conditions and communicate with the display device 20 to adjust the brightness of the display to enhance viewability of the display device 20 under various light conditions.

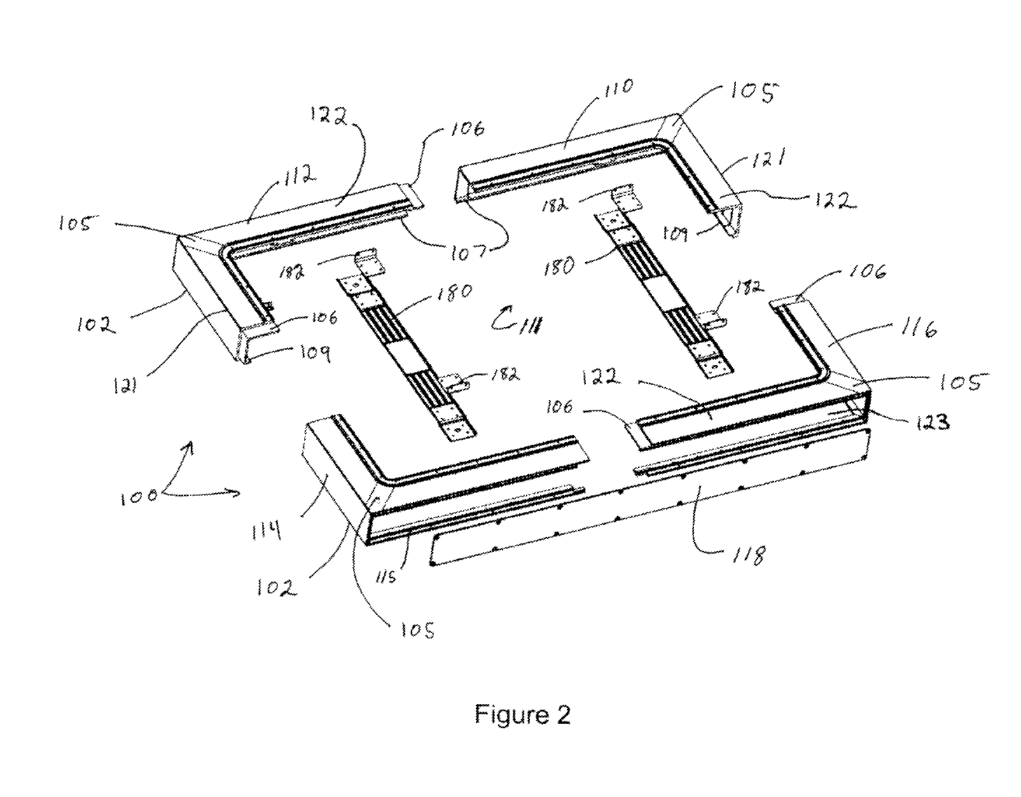

As shown in FIG. 2, the bezel 100 defines the periphery of the display enclosure 10. The bezel 100 is generally sized such that the display device 20 fits within the region defined by the bezel 100. The bezel 100 may comprise a plurality of frame members 105 that are assembled to define the bezel 100. As shown, each of the plurality of frame members 105 is generally of a modified “C-shape” where a rear surface of the member may extend inwardly from a lateral surface beyond a front surface of the member. However, other configurations may also be used, including “L-shaped” and other shaped frame members. The plurality of frame members 105 may be constructed of metal such as aluminum or other material capable of providing sufficient strength and rigidity, while maintaining a low peripheral profile for the display enclosure 10. In other implementations, the plurality of frame members 105 may be constructed of a thermoplastic or other rigid non-metallic material. In the depicted embodiment, the frame members include a first upper frame 110, a second upper frame 112, a first lower frame 114, and a second lower frame 116. The bezel 100 further includes a lower plate 118 coupled to the first lower frame 114 and the second lower frame 116. However, other configurations of the bezel 100 may be constructed, including a single-piece frame, two-piece frame, and frames comprising even more pieces.

As depicted in FIG. 2, some frame members 105 include a frame interface 106 disposed on at least one end of the respective member. When the bezel 100 is assembled, each of the frame interfaces 106 is received by an adjacent frame member 105. The plurality of frame members 105 are assembled to form the perimeter of the bezel 100, defining an outer or peripheral surface 108. The plurality of frame members 105 may be joined using an adhesive such as a high-strength epoxy. However, other techniques for joining the frame members 105 may also be used, including other adhesives, connecting elements, welding, and combinations thereof. The first lower frame 114 and the second lower frame 116 may further include a lower flange 115 configured to interface with the lower plate 118. The lower flange 115 defines a lower opening 123 in the bezel 100. The lower opening 123 is sized to receive the display device 20 during assembly or manufacture of the display enclosure 10. The lower plate 118 is coupled to the first lower frame 114 and the second lower frame 116 at the lower flange 115. The lower plate 118 may be joined to the lower flange 115 by various techniques, including a plurality of connecting elements, adhesive bonding, welding, and combinations thereof. Regardless of the specific construction of the bezel 100, it will be appreciated that, in use, the bezel 100 provides support for the display device 20 and is substantially impervious to liquids and prevents ingress of liquids and other containments into the display enclosure 10 that may be encountered in the mounting environment.

Once the frame members 105 are joined to form the perimeter of the bezel 100, the bezel 100 may undergo an additional treatment or plurality of treatments. These treatments can include, for example, applying an organic coating and/or sealant to the bezel 100, which may be utilized to enhance resistance to environmental effects, strengthen the bezel, and/or provide a decorative coating. Various treatments can include polyurea coatings, urethane coatings, polyurethane coatings, epoxy coatings, powder coating, painting, anodizing, and combinations thereof. The material utilized in a particular treatment may be characterized as being adherable to the bezel 100 or an intermediate material disposed on the bezel and durable under various environmental conditions. Additionally, it may be desirable for the treatment to be characterized by one or more cosmetic attributes such as an ability to conceal surface imperfections in the bezel 100, including seams between the frame members 105, as well as providing a color, texture, and finish suitable for an outdoor display enclosure.

In an embodiment, the bezel 100 is treated with a polyurea coating. The polyurea coating may be applied as a liquid to portions of the bezel 100, such as the external surfaces or selected surfaces, or may be applied to the entire bezel 100. Selected surfaces of the bezel 100 may be coated by masking or other techniques. Application of the polyurea coating may be accomplished by a spray process. In various embodiments, the polyurea coating comprises a two-component system that includes a catalyst to effectuate curing of the polyurea on the bezel 100 at room temperature and without the need for a subsequent heat treating operation. In a particular embodiment, the two-component polyurea has the product designation UL XT 66 and is available from Ultimate Linings, LTD, of Houston Tex. After curing, the polyurea coating provides a weatherproof seal or surface over the applied portions of the bezel.

Various processes may be used to apply the organic coating to the bezel 100, including by pumping the material to a spraying device. Proportioning valves achieve the desired ratio of the two-components, which are mixed into a blended flow prior to discharge from the spaying device onto the bezel. Prior to application, the viscosity of the polyurea may lowered by heating the material in order to improve pumping efficiency and spraying. In a particular embodiment, the components of a two-component polyurea system are heated to about 150° F. In a particular embodiment, the components are proportioned and heated using a Reactor™ proportioning and heating system from Graco Inc. of Minneapolis, Minn.

Two-component polyurea provides a highly durable and weatherproof coating over the bezel 100. In addition to durability, the polyurea can provide an aesthetic finish that does not require a subsequent painting or coating step or a post-application heat treatment step to cure the coating. For example, where the bezel 100 includes external seams between the frame members 105, the polyurea coating can be applied and cured to form a surface that effectively conceals the seams to provide a finish with a uniform surface appearance on the bezel 100. The amount of material applied may be varied to achieve the desired thickness of the coating. In a particular embodiment, a finished polyurea coating of about 0.060 inches is utilized. Accordingly, a two-component polyurea system can enhance manufacturability and efficiency relative to conventional multi-step finishing processes.

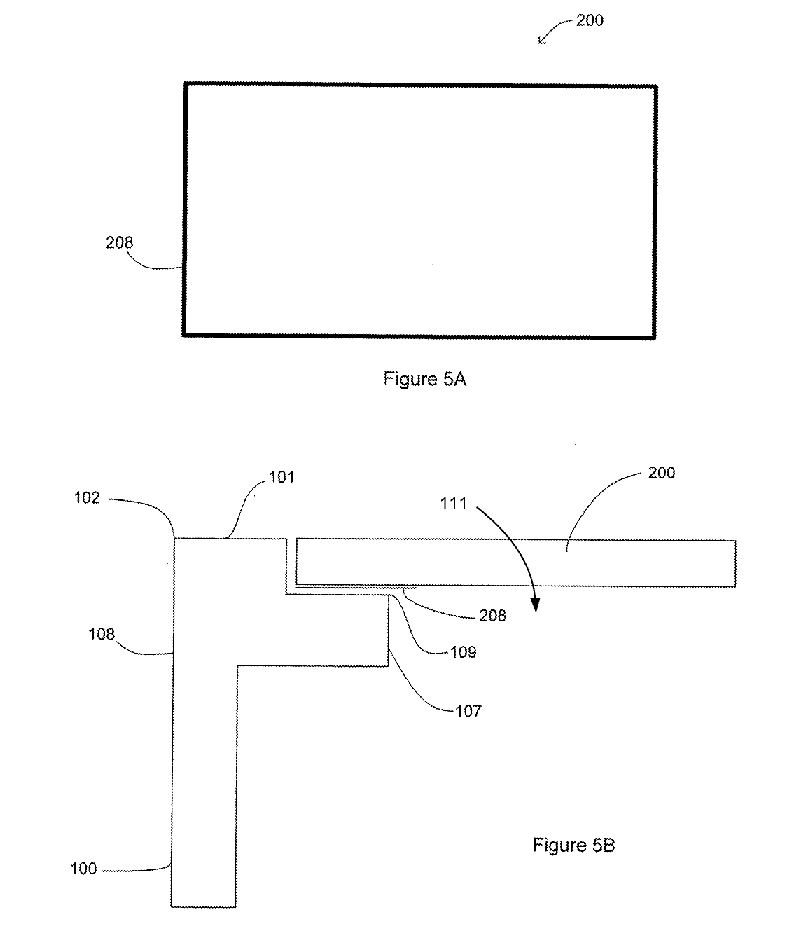

With reference to FIGS. 2 and 5B, the plurality of frame members 105 may form an inner edge 107 along a bezel front surface 101 that extends from a front edge 102 of the bezel 100 that defines the display opening 111. The display area of the display device 20 is visible through the display opening 111. As such, the bezel 100 may be constructed to various dimensions to accommodate display devices 20 of different sizes. For example, the bezel 100 may be constructed in accordance with display device screen sizes that are commonly manufactured. In a particular embodiment, the bezel 100 is constructed to accommodate a 42 inch display device 20.

The bezel 100 is constructed such that the thickness of the bezel, i.e., the normal distance between the inner edge 107 and the peripheral surface 108, the portion visible when viewing the display enclosure 10 from the front, is minimized. That is, the bezel 100 has a low profile surrounding the display opening 111. For example, in a particular embodiment, the distance between inner edge 107 and the outer surface of the display enclosure 10 is less than about 25 mm. In other words, the area of the display opening 111 is maximized relative to the area of the display enclosure 10 defined by the peripheral surface 108. For example, in a particular embodiment, the area of the display opening 111 is at least about 92 percent of the area of the display enclosure 10. The low peripheral profile of the bezel 100 may enhance the overall look of the display enclosure 10, as well as minimizing the space needed in a mounting location for installation of an enclosed display. In multiple screen arrangements, where several displays are positioned horizontally and/or vertically next one another, the low profile of the bezel 100 may provide an enhanced seamless appearance of the displayed image(s) on the multiple display devices 20.

The display opening 111 is covered by the front cover 200. As shown in FIG. 2 and FIG. 5B, the front cover ledge 109 may be disposed along the inner edge 107 and be recessed from the bezel front surface 101 to receive the front cover 200. The front cover ledge 109 may be recessed from the bezel front surface 101 about the thickness of the front cover 200 so that the bezel front surface 101 and the front cover 200 define a substantially smooth surface. In other words, the surface of the front cover 200 is neither perceptibly raised above, nor depressed below the bezel front surface 101. Alternatively, the front cover 200 may extend over the front of the bezel front surface 101 to the outer edge of bezel 100 or a portion thereof. In yet another embodiment, the front cover 200 may be disposed in back of the bezel front surface 101 and received within the bezel 100.

FIGS. 1, 5A and 5B show the front cover 200, which attaches to a front portion of the bezel 100. The front cover 200 comprises a plate of a substantially transparent material that permits viewing of the display device 20 within the display enclosure 10. Accordingly, the front cover 200 may comprise glass or a substantially transparent plastic. In a particular embodiment, the front cover 200 comprises tempered glass. The front cover 200 is joined to the bezel 100 in a manner that prevents ingress of liquids into the display enclosure 10. For example, the front cover 200 may be bonded to the bezel 100 using an adhesive such as a urethane adhesive. As shown in FIGS. 5A and 5B, the front cover 200 may include a border 208 that may be substantially opaque, on the front and/or rear surfaces about the periphery to mask the bonding region between the front cover 200 and the front cover ledge 109. The front cover 200 may further include an anti-reflective coating on the front and/or rear surfaces to reduce photopic reflection. The front cover 200 may also be treated to mitigate ambient ultraviolet (UV) light degradation of the polarizer module of the display device 20. For example, the front cover 200 may include a UV coating configured to shield the polarizer from at least a portion of ambient UV radiation. In various embodiments, the front cover 200 is of sufficient strength to withstand ambient conditions when the display enclosure 10 is located for outdoor viewing. In a particular embodiment, the front cover 200 comprises tempered glass of about 4 mm in thickness.

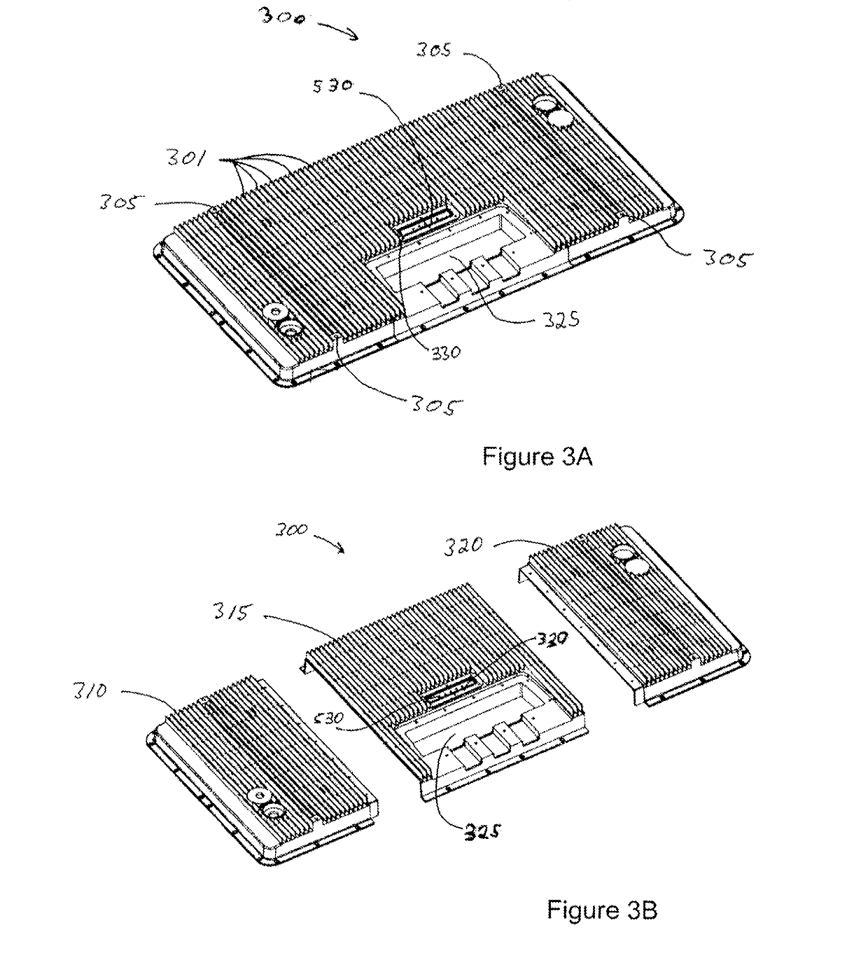

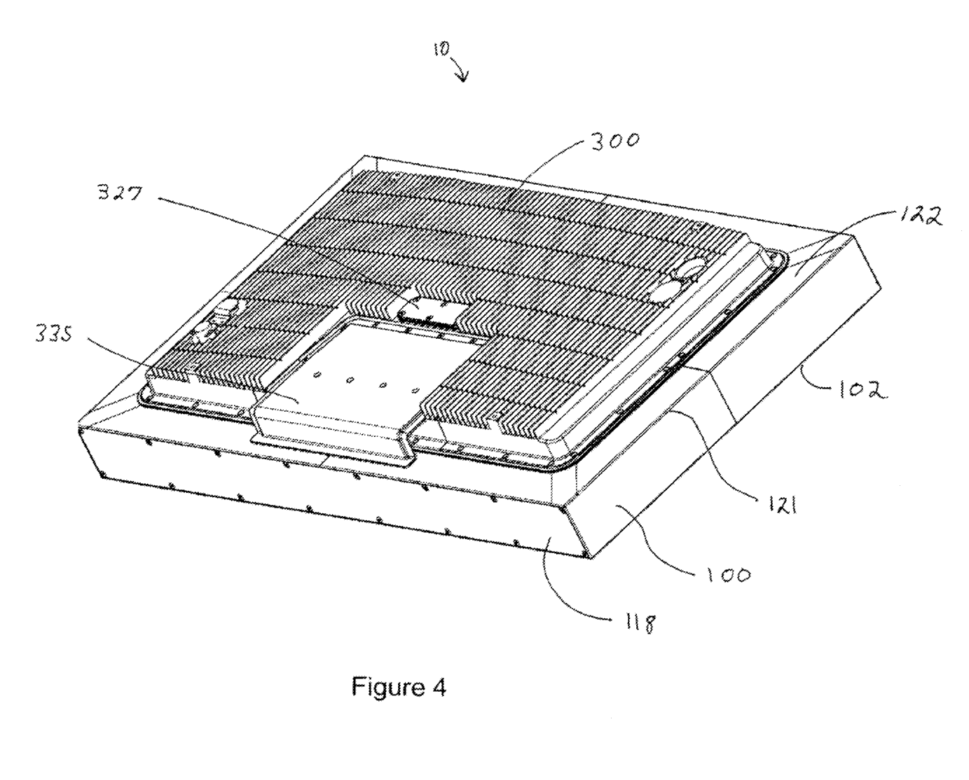

As shown in FIGS. 1 and 4, a rear cover assembly 300 covers the rear portion of the display enclosure 10. More particularly, the rear cover assembly 300 covers the rear opening 311 defined by the bezel 100. The rear cover assembly 300 is attached to a rear surface 122 extending from a rear edge 121 of the bezel 100. The rear cover assembly 300 is joined to the bezel 100 in a manner that prevents ingress of liquids into the display enclosure 10. A plurality of connecting elements may be received about the perimeter of the rear cover assembly 300 in order to join the rear cover assembly 300 to the bezel 100. The use of removable connecting elements allows for installation of and access to the display device 20 within in the display enclosure 10. It will be appreciated that the connection of the rear cover assembly 300 to the bezel 100 is configured to prevent ingress of liquid into the display enclosure 10. In an embodiment, a gasket may be disposed between the rear cover assembly 300 and the bezel 100 to provide appropriate sealing of the display enclosure 10. The rear cover assembly 300 also serves as a heat sink, dissipating heat generated from within the display enclosure 10 to the environment outside the enclosure. As such, at least a portion of the rear cover assembly 300 may comprise a material having a relatively high thermal conductivity. For example, in an embodiment, the rear cover assembly 300 comprises die cast aluminum. As depicted in FIG. 3A, the rear cover assembly 300 assembly may include a heat sink portion that comprises a plurality of fins 301 disposed on the outer surface to enhance convective transfer of heat generated from within the display enclosure 10 to the environment. As discussed above, a thermoelectric module 600 may be coupled (e.g., via connecting elements such as bolts, screws, latches, clamps, clips, etc., via adhesives, or otherwise) or positioned relative to the rear cover assembly 300 such that thermal conduction occurs between the second portion 620 of the thermoelectric module 600 and the rear cover assembly 300. Thus, the thermal energy, either heating or cooling, may be conducted through the rear cover assembly 300 to the plurality of fins 301 for convection to the surrounding environment, as will be discussed in greater detail below.

In various embodiments, the display enclosure 10 is constructed by assembling the plurality of frame members 105 to form the bezel 100. After the bezel 100 is formed, the display device 20 is introduced into the region defined by the bezel 100 through the lower opening 123. With the display device 20 in place within the region defined by the bezel, the lower plate 118 is secured to the bezel 100. By introducing the display device 20 through the lower opening 123 several advantages may be achieved, including a low profile for the bezel 100 and a well sealed enclosure. Because the display device 20 is introduced through the lower opening 123, the dimensions of various portions of the bezel 100 may be increased. For example, the rear surface 122 may be extended towards the interior of the bezel 100 to enhance the structural integrity of the display enclosure 10 with no increase in the profile of the bezel 100 because the display device 20 need not fit through the rear opening defined by the rear surface 122. Additionally, extending the rear surface 122 permits the front portions of the bezel 100, including the front surface 101 and the front cover ledge 109, to have a low profile.

FIG. 3B shows an embodiment of the rear cover assembly 300 that comprises a plurality of panels, including a left panel 310, a central panel 315, and a right panel 320, that are coupled together. Similar to the bezel 100, the left panel 310, the central panel 315, and the right panel 320 may be joined using a high-strength adhesive such as epoxy but may be attached using other techniques, including connecting elements, welding, and combinations thereof. As shown in FIG. 3A, the rear cover assembly 300 may include a plurality of mount attachment features 305 that permit the display enclosure 10 to be coupled to a pedestal, wall mount, ceiling mount, or other mounting system. In an embodiment, the plurality of mount attachment features 305 comprises openings disposed in the rear cover assembly according to an industry standard pattern. The rear cover assembly 300 may include an access area 325 as shown in FIGS. 3A and 3B. The access area 325, for example, provides entry for power and signal cables coupled to the display device 20. With reference to FIGS. 3A and 4, an access cover 327 is attachable to the rear cover assembly 300 and may include cable glands to seal the cable entries, preventing ingress of liquid into the display enclosure 10 at the cable entry point. The rear cover assembly 300 may include a display control access 330 for an on screen display (OSD) interface 530. The OSD interface 530 may include a number of inputs operable by a user that allow for manual control and/or adjustment of settings of the display device 20. A cable entry cover 335 may be installed over the display control access 330 to prevent ingress of liquids into the display enclosure 10.

The display enclosure 10 may include internal supports disposed within the display enclosure 10. As depicted in FIG. 2, the display enclosure 10 includes display brackets 180. The display brackets 180 are attachable to a rear portion of the display device 20. The display brackets 180 generally comprise elongated members with openings for receiving connecting elements to secure the display device 20. The display brackets 180 may be directly coupled to the bezel 100 or, as depicted, by connecting brackets 182 attachable to the bezel 100. The display brackets 180 secure the display device 20 in the display enclosure 10 and provide additional rigidity to the display enclosure 10.

Various other thermal control devices may be disposed within or at least partially within the display enclosure 10, to assist in maintaining the internal temperature of the display enclosure 10. Thermal control may be accomplished by including devices intended to add and/or remove heat from the display enclosure 10 depending on ambient conditions and/or the operating conduction of the display device 20. The various thermal control devices may work independently or in concert to assist in modulating the temperature inside the display enclosure 10 within the operating temperature range and/or storage temperature range of the display device 20 under various ambient conditions. In a particular embodiment, the display enclosure 10 is capable of maintaining the internal temperature inside the enclosure within the operating range of the display device 20 for an ambient temperature range of between about −20° C. and about 60° C. The thermal control devices within the display enclosure 10 may comprise passive and/or active devices.

Referring to FIGS. 6-8, the display enclosure 10 may include one or more thermoelectric modules 600 (more particularly, Peltier thermoelectric modules) associated with the rear cover assembly 300. In the implementation depicted in FIG. 6, the module 600 may be physically coupled to the heat sink portion of the rear cover assembly 300. For example, the thermoelectric module 600 and the rear cover assembly 300 may be coupled together (e.g., via connecting elements such as bolts, screws, latches, clamps, clips, etc. via adhesives, or otherwise) and may include a thermally conductive grease or adhesive 650 interposed between the second portion 620 and the heat sink portion. The thermally conductive grease or adhesive 650 may be a ceramic-based thermal grease (e.g., beryllium oxide), a metal-based thermal grease (e.g., silver or aluminium impregnated grease), a thermal adhesive (e.g., a mixture of epoxy and thermal conductive components, such as silver or aluminium), or any other thermally conductive grease or adhesive. The thermally conductive grease or adhesive 650 may be used to fill any gaps between the second portion 620 of the thermoelectric module 600 and the rear cover assembly 300, thereby increasing the thermal conductivity between the second portion 620 and the heat sink portion.

The first portion 610 of the thermoelectric module 600 faces an interior of the display enclosure 10. When an electric current is applied to the module 600 in a first direction, the first portion 610 is cooled and the second portion 620 is heated. When the electric current is applied to the module 600 in a second direction, opposite the first direction, the first portion 610 is heated and the second portion 620 is cooled.

In the example implementation shown, an internal fan 410 is horizontally positioned above the first portion 610 to draw air towards or away from the first portion 610 to increase the convective heating or cooling of the interior of the display enclosure 10. In some implementations, an internal fan 410 may be vertically positioned adjacent to the first portion 610 (e.g., perpendicular to an interior surface of the first portion 610) in the interior of the display enclosure 10 to draw air over the first portion 610 to increase the convective heating or cooling of the interior of the display enclosure 10. In some implementations, a second heat sink may be conductively coupled to the first portion 610 to increase the convective surface on the interior of the display enclosure 10 as well. The internal fan 410 may be positioned adjacent to and/or above the second heat sink to increase the airflow through the heat sink fins. The thermoelectric module 600 and/or the internal fan 410 are electrically coupled to a power source to provide operating power to the thermoelectric module 600 and/or the internal fan 410.

In some implementations, the thermally conductive grease or adhesive 650 may be omitted and the thermoelectric module 600 may simply abut and otherwise be conductively coupled to the rear cover assembly 300. In still other implementations, the thermoelectric module 600 may be coupled to other portions of the display enclosure 10, such as a side or other portion of the bezel 100. The side or other portion of the bezel 100 may include a heat sink for convectively dissipating the cooling or heating of the second portion 620 of the thermoelectric module 600. Still further, a plurality or an array of thermoelectric modules 600 may be used.

In another implementation, shown in FIG. 7, the thermoelectric module 600 may be embedded or integrated into the rear cover assembly 300. In the example shown, a recess 380 is formed in a portion of the rear cover assembly 300 such that all or a portion of the second portion 620 of the thermoelectric module 600 may be inserted into the recess 380. Thus, additional surface area of the second portion 620 may be conductively coupled to the rear cover assembly 300, thereby increasing the heat transfer between the second portion 620 and the rear cover assembly 300. The thermoelectric module 600 and the rear cover assembly 300 may be coupled together (e.g., via connecting elements such as bolts, screws, latches, clamps, clips, etc. via adhesives, or otherwise). In some implementations, the thermally conductive grease or adhesive may be interposed between the second portion 620 and the surface of the recess of the rear cover assembly 300 to increase the thermal conductivity.

In some implementations, the internal fan 410 may be positioned above (as shown) and/or adjacent to the embedded thermoelectric module 600 to increase air flow over the first portion 610 to increase the convective heating or cooling of the interior of the display enclosure 10. In some implementations, a second heat sink may be thermally coupled to the first portion 610 to increase the convective surface on the interior of the display enclosure 10 as well. The internal fan 410 may be positioned adjacent to and/or above the second heat sink to increase the airflow through the heat sink fins. The thermoelectric module 600 and/or the internal fan 410 are electrically coupled to a power source to provide operating power to the thermoelectric module 600 and/or the internal fan 410.

In some implementations, the thermoelectric module 600 may be embedded within the rear cover assembly 300 such that an outer surface of the first portion 610 is flush with the interior surface of the rear cover assembly 300. In still other implementations, the thermoelectric module 600 may be embedded or integrated into other portions of the display enclosure 10, such as a side or other portion of the bezel 100. The side or other portion of the bezel 100 may include a heat sink for convectively dissipating the cooling or heating of the second portion 620 of the thermoelectric module 600. Still further, a plurality or an array of thermoelectric modules 600 may be used.

In still another implementation, shown in FIG. 8, the rear cover assembly 300 may include an opening 390 for the second portion 620 of the thermoelectric module 600 to be exposed to the external environment. Thus, the atmospheric air may convectively transfer heat to or from the second portion 620. In some implementations, an outer surface of the second portion 620 may be flush with a surface of the rear cover assembly 300, such as that shown in FIG. 8. In other implementations, the second portion 620 may protrude outward from or be recessed relative to the rear cover assembly 300. The thermoelectric module 600 may be bonded to the rear cover assembly 300 in a manner that prevents ingress of liquids into the display enclosure 10. For example, the thermoelectric module 600 may be bonded to the rear cover assembly 300 using an adhesive such as a urethane adhesive. In some implementations, the thermoelectric module 600 and the rear cover assembly 300 may be physically coupled together (e.g., via connecting elements such as bolts, screws, latches, clamps, clips, etc.), either in addition to or in lieu of the adhesive bonding.

The internal fan 410 may be positioned above (as shown) and/or adjacent to the thermoelectric module 600 to increase air flow over the first portion 610 to increase the convective heating or cooling of the interior of the display enclosure 10. In some implementations, a second heat sink may be thermally coupled to the first portion 610 to increase the convective surface on the interior of the display enclosure 10 as well. The internal fan 410 may be positioned adjacent to and/or above the second heat sink to increase the airflow through the heat sink fins. The thermoelectric module 600 and/or the internal fan 410 are electrically coupled to a power source to provide operating power to the thermoelectric module 600 and/or the internal fan 410.

The thermoelectric module 600 may be positioned within the rear cover assembly 300 such that an outer surface of the first portion 610 is flush with the interior surface of the rear cover assembly 300. In still other implementations, the thermoelectric module 600 positioned with the second portion 620 exposed in other portions of the display enclosure 10, such as a side or other portion of the bezel 100. Still further, a plurality or an array of thermoelectric modules 600 may be used.

In addition to, or in lieu of, the fans discussed above in reference to the thermoelectric modules 600, the display enclosure 10 may also include additional internal fans 410 located within the display enclosure 10, such as that shown in FIG. 1. Each internal fan 410 may circulate air within the display enclosure 10, mitigating thermal gradients or hot spots on, for example, a surface of the display device 20 and regions within the display enclosure 10. The internal fan 410 is electrically coupled to a power source to provide operating power to the internal fan 410.

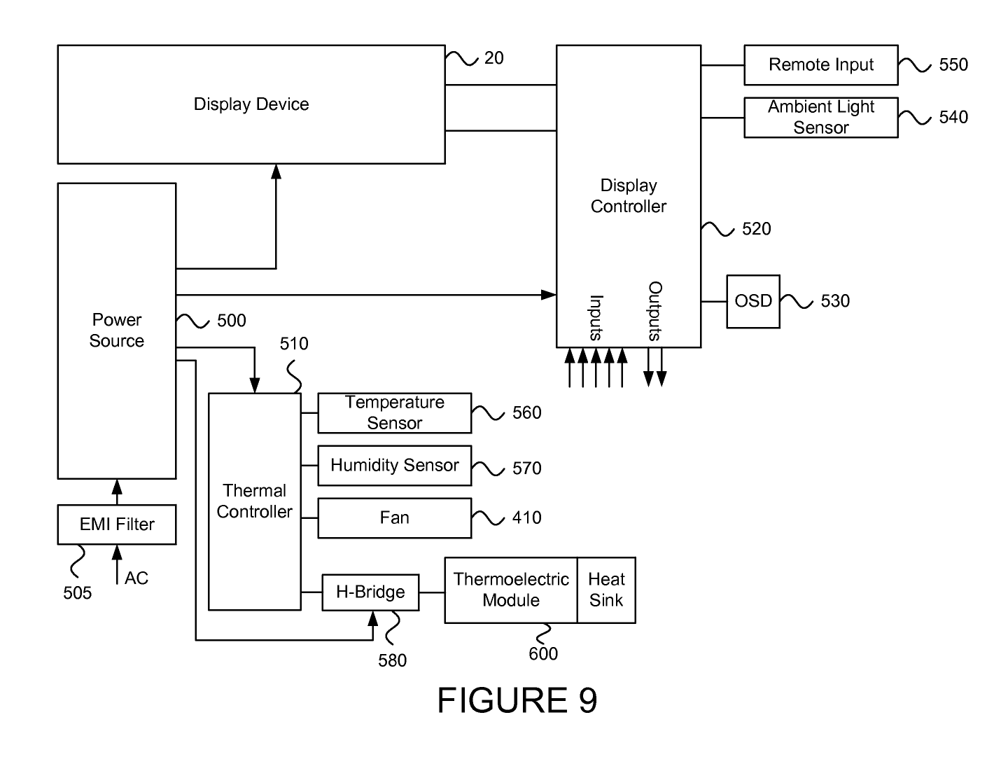

FIG. 9 depicts a block diagram illustrating components of the display enclosure 10 with the display device 20. A power supply 500 may be included within the display enclosure 10 to provide direct or indirect power to the thermoelectric module or modules 600, the internal fan or fans 410, a temperature sensor 560, a humidity sensor 570, a remote control input 550, an ambient light sensor 540, the display device 20, a display controller 520, a thermal controller 510 and other devices within the display enclosure 10. As shown in FIG. 1, the power supply 500 may be mounted within the display enclosure 10. The power supply 500 is electrically coupled to a power source, for example, directly or indirectly to a conventional power grid or other source. An EMI filter 505, shown in FIG. 9, may be included between the power source and the power supply 500. In addition to the display device 20, the power supply 500 may be a significant heat generator that may raise the internal temperature within the display enclosure 10 when in operation. Accordingly, in some implementations a Peltier thermoelectric module 600 may be located between the power supply 500 and the rear cover assembly 300 such that the thermoelectric module 600 may actively cool the power supply 500 and/or the interior of the display enclosure 10. As noted above, the thermoelectric module 600 may be conductively coupled to the rear cover assembly 300 such that thermal energy may be conducted to the heat sink portion of the rear cover assembly 300. In some instances, such as when the display enclosure 10 is within a cold environment, the thermoelectric module 600 may heat the power supply 500 and/or the interior of the display enclosure 10.

Still referring to FIG. 9, the power supply 500 provides power to a display controller 520. The display controller 520 controls the display device 20 and may be mounted within display enclosure 10. Alternatively, the display controller 520 may be integral with the display device 20. As shown in FIG. 9, the display controller 520 is electrically coupled to the power supply 500, the display device 20, and the OSD interface 530. The display controller 520 includes inputs for receiving typical audio/visual signals, e.g. HDMI, VGA, PC audio input, component video, S-video, composite video, SPDIF, audio inputs, and ATSC/cable tuner. The display controller 520 includes processing components for output of a signal for display by the display device 20. An audio output from the display controller 520 may be directed to the display device 20 or to stand alone audio equipment that may be situated outside the display enclosure 10. The display controller 520 is also coupled to OSD accessible from the rear of the display enclosure 10.

The display enclosure 10 may also be provided with an ambient light sensor 540. The ambient light sensor 540 senses the light level outside the display enclosure 10 and may be mounted to the bezel 100 or beneath the front cover 200. The ambient light sensor 540 is electrically coupled to the power supply 500 and the display controller 520. The display controller 520 receives input from the ambient light sensor 540 and, based on the input signal, may be configured to adjust the displayed image, for example, the brightness and/or the contrast, generated by the display device 20. For instance, under relatively low ambient light conditions, such as at night when the display enclosure 10 is located outdoors, the display controller 520 may be configured to automatically decrease the brightness of the display device 20 based on the input from the ambient light sensor 540. In other instances, such as under relatively bright ambient light conditions, such as during the day when the display enclosure 10 is located outdoors, the display controller 520 may be configured to automatically increase the brightness of the display device 20 based on the input from the ambient light sensor 540.

The display enclosure 10 may also be equipped with features that enable communication between the display device 20 and a remote control device configured to control and the display device 20. The display enclosure 10 may include a remote control input 550. The remote control input 550 comprises an infrared sensor in a particular embodiment. The remote control input 550 is electrically coupled to the display controller 520 and may be mounted to the bezel 100 or located beneath the front cover 200 to receive input from a separate remote control device configured to control the operation of the display device.

In addition to the display controller 520, the display enclosure 10 includes a thermal controller 510. As shown in FIG. 9, the thermal controller 510 is electrically coupled to the power supply 500 to receive power. The thermal controller 510 is also electrically coupled to the temperature sensor 560, the humidity sensor 570, the one or more fans 410, and an H-Bridge 580. The thermal controller 510 may be configured to control the heating or cooling of the first portion 610 of the thermoelectric module 600. In one implementation, the thermal controller 510 may receive an output from the temperature sensor 560, such as a value indicative of an internal temperature of the display enclosure 10, and an output from the humidity sensor 570, such as a value indicative of an internal humidity of the display enclosure 10, and control the operation of the one or more fans 410 and the thermoelectric module 600.

The temperature sensor 560 is electrically coupled to the thermal controller 510 and the power supply 500 and is configured to output a signal indicative of a temperature detected by the temperature sensor 560. The temperature sensor 560 may include a thermistor, a thermocouple, a resistance temperature detector, or any other temperature sensor. The signal output from the temperature sensor 560 may be a voltage value that corresponds to a detected temperature. The thermal controller 510 may receive and use the voltage value representative of the temperature as an input for controlling the one or more fans 410 and/or the thermoelectric module 600, as will be described in greater detail below.

The temperature sensor 560 is positioned within the display enclosure 10 to measure the internal temperature of the display enclosure 10. In some implementations, the temperature sensor 560 may be positioned near the thermoelectric module 600. For example, the temperature sensor 560 may be positioned adjacent to a thermoelectric module 600. In other instances, the temperature sensor 560 may be positioned remote from the thermoelectric module 600, such as at an opposite corner of the display enclosure 10 relative to the thermoelectric module 600. In still further implementations, the temperature sensor 560 may be arbitrarily positioned within the display enclosure 10.

The humidity sensor 570 is also electrically coupled to the thermal controller 510 and the power supply 500 and is configured to outputs a signal indicative of a humidity detected by the humidity sensor 570. The humidity sensor 570 may include a hygrometer, a humistor, or any other humidity sensor. The signal output from the humidity sensor 570 may be a voltage value that corresponds to a detected humidity, such as a relative humidity. The thermal controller 510 may receive and use the voltage value representative of the humidity as an input for controlling the one or more fans 410 and/or the thermoelectric module 600, as will be described in greater detail below.

The humidity sensor 570 is positioned within the display enclosure 10 to measure the internal humidity of the display enclosure 10. In some implementations, the humidity sensor 570 may be positioned near the temperature sensor 560 and/or the thermoelectric module 600. For example, the humidity sensor 570 may be positioned adjacent to the temperature sensor 560 such that the humidity and temperature measurements are taken at substantially the same spatial position. In other instances, the humidity sensor 570 may be positioned remote from the temperature sensor 560. In still further implementations, the humidity sensor 570 may be arbitrarily positioned within the display enclosure 10. In some implementations, the humidity sensor 570 may be omitted.

The thermal controller 510 is further electrically coupled to the H-Bridge 580. The H-Bridge 580 is also electrically coupled to one or more thermoelectric modules 600 and the power supply 500. The thermal controller 510 is configured to control the direction of current supplied from the power supply 500 to the one or more thermoelectric modules 600 via the H-Bridge 580. In one implementation, the thermal controller 510 may control the current flow to the one or more thermoelectric modules 600 by using one half of the H-Bridge 580. That is, the thermal controller 510 may, using the H-Bridge 580, control whether current flows in a first direction or a second direction through the thermoelectric modules 600. As noted above, when an electric current is applied to the one or more thermoelectric modules 600 in the first direction, the first portion 610 of each thermoelectric module 600 is cooled and the second portion 620 of each thermoelectric module 600 is heated. When the electric current is applied to the one or more thermoelectric modules 600 in the second direction, opposite the first direction, the first portion 610 of each thermoelectric module 600 is heated and the second portion 620 of each thermoelectric module 600 is cooled. The second portion 620 may be conductively coupled to or otherwise associated with the rear cover assembly 300 for heat transfer to the external atmosphere of the display enclosure 10. Accordingly, it may be appreciated that the internal temperature of the display enclosure 10 and/or portions thereof may be actively regulated by the thermal controller 510 using the H-Bridge 580.

The thermal controller 510 may control the current flowing through the one or more thermoelectric modules 600 using pulse width modulation (PWM). The thermal controller 510 may control the duty cycle of the pulse width modulation to vary the heating or cooling provided by the one or more thermoelectric modules 600. When the duty cycle of the pulse width modulation reaches 100%, then the maximum current is applied and the maximum heating or cooling is provided by the one or more thermoelectric modules 600.

One or more fans 410 may be electrically coupled the thermal controller 510 and the power supply 500. The thermal controller 510 may be configured to control the one or more fans 410. As discussed above, the one or more fans 410 may be positioned to circulate air within the display enclosure 10. In some implementations, the one or more fans 410 may be positioned relative to the one or more thermoelectric modules 600 to increase the convective heat transfer from the first portion 610 (e.g., adjacent to, above, etc.) to the interior air of the display enclosure 10 to assist the heating or cooling provided by the first portion 610 of the one or more thermoelectric modules 600.

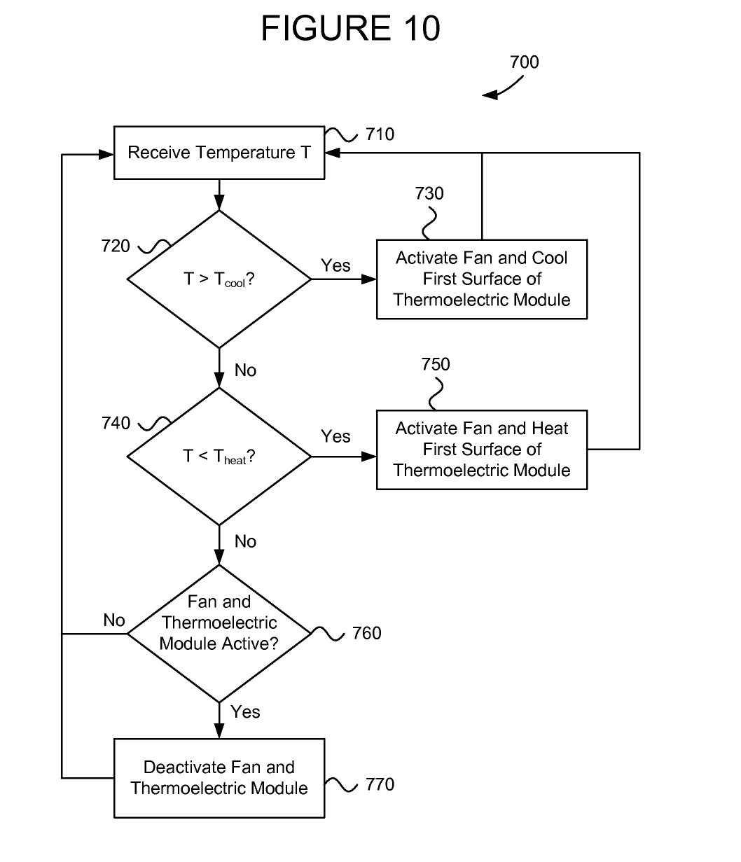

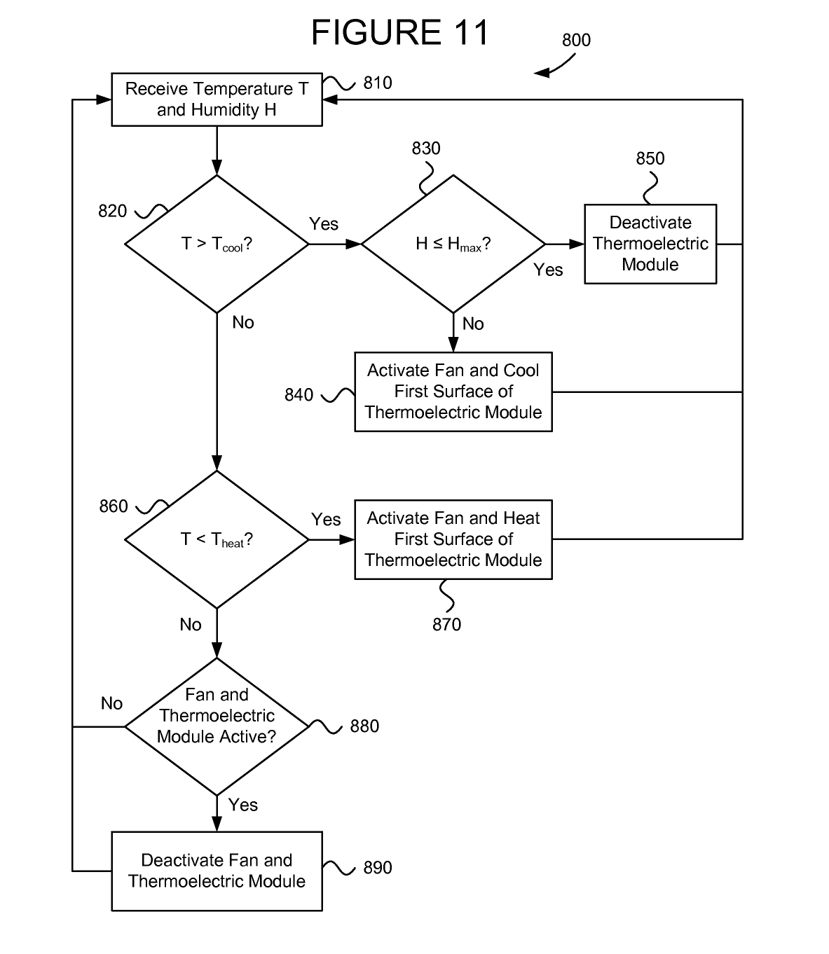

Referring to FIGS. 10 and 11, the thermal controller 510 may be configured with one or more temperature set points, such as T_{cool} and Tₕₑₐₜ. Using the one or more temperature set points, the thermal controller 510 may be configured to control the one or more fans 410 and/or the one or more thermoelectric modules 600. In one example configuration, shown as process 700 in FIG. 10, the thermal controller 510 may receive a temperatureT from the temperature sensor 560 (block 710). The received temperature may be represented by a voltage outputted by the temperature sensor 560 to the thermal controller 510 that is indicative of the temperature detected by the temperature sensor 560. The received temperature T may be compared against a first temperature set point, such as T_{cool}, by the thermal controller 510 to determine whether the temperature detected T by the temperature sensor 560 is above a first temperature set point (block 720). In an exemplary implementation, the first temperature set point may be between 30° C., inclusive, and 45° C., inclusive. In one particular example, the first temperature set point T_{cool} may be set at approximately 30° C.

If it is determined that the detected temperature T is above the first temperature set point, T_{cool} (block 720) then the thermal controller 510 may be configured to activate one or more of the fans 410 and switch the H-bridge 580 to energize and drive current thru the one or more thermoelectric modules 600 in the direction which will cause the first surface 610 of each of the one or more thermoelectric modules 600 to be cooled (block 730). Accordingly, the interior of the display enclosure 10 may be cooled by the one or more thermoelectric modules 600 and the one or more fans 410 circulating air. The second portion 620 of the one or more thermoelectric modules 600 may be coupled to the heat sink portion of the rear cover assembly 300. When the second portion 620 is heated as the first portion 610 is cooled, the second portion 620 thermally conducts heat through the heat sink portion of the rear cover assembly 300 to dissipate the heat to the atmosphere. The process 700 may then return to block 710 to receive the temperature T from the temperature sensor 560. In some implementations, the thermal controller 510 is configured to operate the one or more fans 410 and the one or more thermoelectric modules 600 until the detected temperature T falls below the first temperature set point T_{cool} as shown in FIG. 10. In other implementations, the thermal controller 510 may be configured to operate the one or more fans 410 and the one or more thermoelectric modules 600 for a predetermined period of time, either in addition to or in lieu of the detected temperature T falling below the first temperature set point T_{cool}. In some implementations, if the one or more fans 410 and the one or more thermoelectric modules 600 are already activated, then the thermal controller 510 may simply keep the one or more fans 410 and the one or more thermoelectric modules 600 activated.

If it is determined that the detected temperature T does not exceed the first temperature set point T_{cool} (block 720), then a determination may be made by the thermal controller 510 whether the detected temperature T is below a second temperature set point Tₕₑₐₜ (block 740). The second temperature set point may be set as a temperature below the operational range of the display device 20 or that would degrade the operation of the display device 20. In some implementations, the second temperature set point may be between −20° C., inclusive, and 10° C., inclusive. In one example, the second temperature set point may be set at approximately 5° C.

If it is determined that the detected temperature T is below the second temperature set point Tₕₑₐₜ (block 740) then the thermal controller 510 may be configured to activate one or more of the fans 410 and switch the H-bridge 580 to energize and drive current thru the one or more thermoelectric modules 600 in the direction which will cause the first surface 610 of each of the one or more thermoelectric modules 600 to be heated (block 750). Accordingly, the interior of the display enclosure 10 may be heated by the one or more thermoelectric modules 600 and the one or more fans 410 circulating air. The second portion 620 of the one or more thermoelectric modules 600 may be coupled to the heat sink portion of the rear cover assembly 300. When the second portion 620 is cooled as the first portion 610 is heated, the second portion 620 thermally cools the heat sink portion of the rear cover assembly 300 through conduction to dissipate the cool to the atmosphere. The process 700 may then return to block 710 to receive the temperature T from the temperature sensor 560. In some implementations, the thermal controller 510 is configured to operate the one or more fans 410 and the one or more thermoelectric modules 600 until the detected temperature T increases above the second temperature set point Tₕₑₐₜ as shown in FIG. 10. In other implementations, the thermal controller 510 may be configured to operate the one or more fans 410 and the one or more thermoelectric modules 600 for a predetermined period of time, either in addition to or in lieu of the detected temperature T increasing above the second temperature set point Tₕₑₐₜ In some implementations, if the one or more fans 410 and the one or more thermoelectric modules 600 are already activated, then the thermal controller 510 may simply keep the one or more fans 410 and the one or more thermoelectric modules 600 activated.

If it is determined that the detected temperature T is not below the second temperature set point Tₕₑₐₜ, (block 740), then a determination may be made by the thermal controller 510 whether the one or more fans 410 and the one or more thermoelectric modules 600 are active (block 760). If the one or more fans 410 and the one or more thermoelectric modules 600 are not active, then the process 700 may return to block 710 to receive the temperature T from the temperature sensor 560. If the one or more fans 410 and the one or more thermoelectric modules 600 are active, then the process 700 may proceed to deactivate the one or more fans 410 and the one or more thermoelectric modules 600 (block 770). The process 700 may then return to block 710 to receive the temperature T from the temperature sensor 560.

In some implementations, the one or more fans 410 and the one or more thermoelectric modules 600 may be operated by the thermal controller 510 while the display device 20 is off or in a sleep mode to mitigate potential damage to the display device 20 that could be caused by ambient temperatures below a storage temperature of the device, such as, for example, below −20° C. or above 45° C. In some other implementations, the process 700 may be performed periodically, such as every minute, five minutes, ten minutes, thirty minutes, one hour, etc.

In another example configuration, shown as process 800 in FIG. 11, the thermal controller 510 may receive a temperature T from the temperature sensor 560 and a humidity H from the humidity sensor 570 (block 810). The received temperature may be a voltage outputted by the temperature sensor 560 to the thermal controller 510 that is indicative of the temperature detected by the temperature sensor 560. The received humidity may also be a voltage outputted by the humidity sensor 570 to the thermal controller 510 that is indicative of the humidity detected by the humidity sensor 570.

The received temperature T may be compared against a first temperature set point, such as T_{cool}, to determine whether the temperature detected T by the temperature sensor 560 is above a first temperature set point (block 820). In some implementations, the first temperature set point may be between 30° C., inclusive, and 45° C., inclusive. In one example, the first temperature set point T_{cool} may be set at approximately 30° C.

If it is determined that the detected temperature T is above the first temperature set point T_{cool}, (block 820), then a determination may be made by the thermal controller 510 whether the received humidity H is less than or equal to a maximum humidity Hₘₐₓ (block 830). For example, the maximum humidity Hₘₐₓ may be a value indicative of a relative humidity between 75% and 100%. In one example, the maximum humidity Hₘₐₓ may be set as a value indicative of a relative humidity of approximately 85%. If the value of the received humidity H within the display enclosure 10 is below the maximum humidity Hₘₐₓ, then the thermal controller 510 may be configured to activate one or more of the fans 410 and switch the H-bridge 580 to energize and drive current thru the one or more thermoelectric modules 600 in the direction which will cause the first surface 610 of each of the one or more thermoelectric modules 600 to be cooled (block 840). Accordingly, the interior of the display enclosure 10 may be cooled by the one or more thermoelectric modules 600 and the one or more fans 410 circulating air. The second portion 620 of the one or more thermoelectric modules 600 may be coupled to the heat sink portion of the rear cover assembly 300. When the second portion 620 is heated as the first portion 610 is cooled, the second portion 620 thermally conducts heat through the heat sink portion of the rear cover assembly 300 to dissipate the heat to the atmosphere. The process 800 may then return to block 810 to receive the temperature T from the temperature sensor 560 and the humidity H from the humidity sensor 570. In some implementations, the thermal controller 510 is configured to operate the one or more fans 410 and the one or more thermoelectric modules 600 until the detected temperature T falls below the first temperature set point T_{cool}, as shown in FIG. 11. In other implementations, the thermal controller 510 may be configured to operate the one or more fans 410 and the one or more thermoelectric modules 600 for a predetermined period of time, either in addition to or in lieu of the detected temperature T falling below the first temperature set point T_{cool}. In some implementations, if the one or more fans 410 and the one or more thermoelectric modules 600 are already activated, then the thermal controller 510 may simply keep the one or more fans 410 and the one or more thermoelectric modules 600 activated.

If the value of the received humidity H within the display enclosure 10 increases above the maximum humidity Hₘₐₓ, then condensation may occur within the display enclosure 10. Such condensation may potentially harm the components of the display enclosure 10 and/or the display device 20. Accordingly, if the value of the received humidity H increases above the maximum humidity Hₘₐₓ, (block 830), then the thermal controller 510 may be configured to deactivate the one or more thermoelectric modules 600 (block 850). In the present example, the one or more fans 410 may remain active to circulate the air within display enclosure 10 to assist in the transfer of thermal energy from the air within the display enclosure 10 to the heat sink portion of the rear cover assembly 300, even if the one or more thermoelectric module 600 is no longer active. In another implementation, both of the one or more fans 410 and the one or more thermoelectric modules 600 may be deactivated when the received humidity H is above a maximum humidity Hₘₐₓ (block 830). In some implementations, a dew point temperature may be determined by the thermal controller 510 based on the received temperature T and the received humidity H. The received temperature T may be compared to the calculated dew point temperature in lieu of, or in addition to, the comparison of the received humidity H, is above a maximum humidity Hₘₐₓ by the thermal controller 510 (block 830). The process 800 may then return to block 810 to receive the temperature T from the temperature sensor 560 and the humidity H from the humidity sensor 570.

If it is determined that the detected temperature T does not exceed the first temperature set point T_{cool}, (block 820), then a determination may be made by the thermal controller 510 whether the detected temperature T is below a second temperature set point Tₕₑₐₜ (block 860). The second temperature set point may be set as a temperature below the operational range of the display device 20 or that would degrade the operation of the display device 20. In some implementations, the second temperature set point may be between −20° C., inclusive, and 10° C., inclusive. In one example, the second temperature set point may be set at approximately 5° C.

If it is determined that the detected temperature T is below the second temperature set point Tₕₑₐₜ, (block 860) then the thermal controller 510 may be configured to activate one or more of the fans 410 and switch the H-bridge 580 to energize and drive current thru the one or more thermoelectric modules 600 in the direction which will cause the first surface 610 of each of the one or more thermoelectric modules 600 to be heated (block 870). Accordingly, the interior of the display enclosure 10 may be heated by the one or more thermoelectric modules 600 and the one or more fans 410 circulating air. The second portion 620 of the one or more thermoelectric modules 600 may be coupled to the heat sink portion of the rear cover assembly 300. When the second portion 620 is cooled as the first portion 610 is heated, the second portion 620 thermally cools the heat sink portion of the rear cover assembly 300 through conduction to dissipate the cool to the atmosphere. The process 800 may then return to block 810 to receive the temperature T from the temperature sensor 560 and the humidity H from the humidity sensor 570. In some implementations, the thermal controller 510 is configured to operate the one or more fans 410 and the one or more thermoelectric modules 600 until the detected temperature T increases above the second temperature set point Tₕₑₐₜ, as shown in FIG. 11. In other implementations, the thermal controller 510 may be configured to operate the one or more fans 410 and the one or more thermoelectric modules 600 for a predetermined period of time, either in addition to or in lieu of the detected temperature T increasing above the second temperature set point Tₕₑₐₜ. In some implementations, if the one or more fans 410 and the one or more thermoelectric modules 600 are already activated, then the thermal controller 510 may simply keep the one or more fans 410 and the one or more thermoelectric modules 600 activated.

If it is determined that the detected temperature T is not below the second temperature set point Tₕₑₐₜ, (block 860), then a determination may be made by the thermal controller 510 whether the one or more fans 410 and the one or more thermoelectric modules 600 are active (block 880). If the one or more fans 410 and the one or more thermoelectric modules 600 are not active, then the process 800 may then return to block 810 to receive the temperature T from the temperature sensor 560 and the humidity H from the humidity sensor 570. If the one or more fans 410 and the one or more thermoelectric modules 600 are active, then the process 800 may proceed to deactivate the one or more fans 410 and the one or more thermoelectric modules 600 (block 890). The process 800 may then return to block 810 to receive the temperatureT from the temperature sensor 560 and the humidity H from the humidity sensor 570.

In some implementations, the one or more fans 410 and the one or more thermoelectric modules 600 may be operated by the thermal controller 510 while the display device 20 is off or in a sleep mode to mitigate potential damage to the display device 20 that could be caused by ambient temperatures below a storage temperature of the device, such as, for example, below −20° C. or above 45° C. In some other implementations, the process 800 may be performed periodically, such as every minute, five minutes, ten minutes, thirty minutes, one hour, etc.

In some implementations, a pair of cooling temperature set points T_{cool}_{_}₁ and T_{cool}_{_}₂ may be used by the thermal controller 510 when activating the one or more thermoelectric modules 600. For example, in one configuration, when the received temperature T is above the first cooling temperature set point T_{cool}_{_}₁, then the thermal controller 510 may activate the one or more fans 410 while the one or more thermoelectric modules 600 remain deactivated. If the received temperature T is above the second cooling temperature set point T_{cool}_{_}₂, then the thermal controller 510 may also activate the one or more thermoelectric modules 600 such that the first portion 610 of each is cooled. In some implementations, the thermal controller 510 is configured to operate the one or more fans 410 and the one or more thermoelectric modules 600 until the detected temperature T falls below the second cooling temperature set point T_{cool}_{_}₂. When the detected temperature T falls below the second cooling temperature set point T_{cool}_{_}₂, then the one or more thermoelectric modules 600 may be deactivated by the thermal controller 510 while the one or more fans 410 remain activated. When the detected temperature T falls below the first cooling temperature set point T_{cool}_{_}₁, then the one or more fans 410 may be deactivated as well. In other implementations, both the one or more fans 410 and the one or more thermoelectric modules 600 may remain active until the detected temperature T falls below the first cooling temperature set point T_{cool}_{_}₁. In other implementations, the thermal controller 510 may be configured to operate the one or more fans 410 and/or the one or more thermoelectric modules 600 for a predetermined period of time after the received temperature T is above the first and/or the second cooling temperature set points T_{cool}_{_}₁ and T_{cool}_{_}₂. The first and second cooling temperature set points T_{cool}_{_}₁ and T_{cool}_{_}₂ may be between 30° C., inclusive, and 45° C., inclusive. In one example, the first cooling temperature set point T_{cool}_{_}₁, may be set at approximately 30° C. and the second cooling temperature set point T_{cool}_{_}₂ may be set at approximately 35° C. Such a pair of cooling temperature set points may be used as part of process 700 at blocks 720 and 730 of FIG. 10 or process 80 at blocks 820 and 840 of FIG. 11.

In yet another implementation, the pair of cooling temperature set points T_{cool}_{_}₁ and T_{cool}_{_}₂ may be used to incrementally increase the cooling provided by the first portion 610 of each of the one or more thermoelectric modules 600. For example, in one configuration, when the received temperature T is above the first cooling temperature set point T_{cool}_{_}₁, then the thermal controller 510 may activate the one or more fans 410 and the one or more thermoelectric modules 600 to cool the interior of the display enclosure 10. The thermal controller 510 may be configured to control the current flowing through the one or more thermoelectric modules 600 using pulse width modulation (PWM). The duty cycle for the pulse width modulation may be determined based on the received temperature T relative to the first and second cooling temperature set points T_{cool}_{_}₁ and T_{cool}_{_}₂. For example, the first and second cooling temperature set points T_{cool}_{_}₁ and T_{cool}_{_}₂ may be between 30° C., inclusive, and 45° C., inclusive. In one example, the first cooling temperature set point T_{cool}_{_}₁ may be set at approximately 30° C. and the second cooling temperature set point T_{cool}_{_}₂ may be set at approximately 35° C. In one example, the duty cycle for the pulse width modulation may be determined by

$$DutyCycle = ( \frac{T - {T}_{cool\_ 1}}{{T}_{cool\_ 2} - {T}_{cool\_ 1}} ) \times 100 \% .$$

Thus, the thermal controller 510 may increase the duty cycle of the pulse width modulation provided to control the thermoelectric module 600, and therefore the cooling effect provided, based on the temperature T detected by the temperature sensor 560 relative to the cooling temperature set points. Of course it should be understood that the cooling temperature set points are merely examples and other cooling temperature set points may be used. Such a pair of cooling temperature set points and control of the thermoelectric modules 600 via pulse width modulation duty cycle may be used as part of process 700 at blocks 720 and 730 of FIG. 10 or process 80 at blocks 820 and 840 of FIG. 11.

Similarly, in some implementations, a pair of heating temperature set points Tₕₑₐₜ_{_}₁ and Tₕₑₐₜ_{_}₂ may be used by the thermal controller 510. For example, in one configuration, when the received temperature T falls below the first heating temperature set point Tₕₑₐₜ_{_}₁ then the thermal controller 510 may activate the one or more thermoelectric modules 600 such that the first portion 610 of each is heated while the one or more fans 410 remain deactivated. If the received temperature T falls below the second heating temperature set point Tₕₑₐₜ_{_}₂ then the thermal controller 510 may also activate the one or more fans 410 to further circulate the heated air from the first portions 610 of each of the one or more thermoelectric modules 600. In some implementations, the thermal controller 510 is configured to operate the one or more fans 410 and the one or more thermoelectric modules 600 until the detected temperature T increases above the second heating temperature set point Tₕₑₐₜ_{_}₂ When the detected temperature T increases above the second heating temperature set point Tₕₑₐₜ_{_}₂ then the one or more thermoelectric modules 600 may be deactivated by the thermal controller 510 while the one or more fans 410 remain activated to circulate the air within the display enclosure 10. When the detected temperature T increases above the first heating temperature set point Tₕₑₐₜ_{_}₁ then the one or more fans 410 may be deactivated as well. In other implementations, both the one or more fans 410 and the one or more thermoelectric modules 600 may remain active until the detected temperature T increases above the first heating temperature set point Tₕₑₐₜ_{_}₁. In other implementations, the thermal controller 510 may be configured to operate the one or more fans 410 and/or the one or more thermoelectric modules 600 for a predetermined period of time after the received temperature T increases above the first and/or the second heating temperature set points Tₕₑₐₜ_{_}₁ and Tₕₑₐₜ_{_}₂. The first and second heating temperature set points Tₕₑₐₜ_{_}₁ and Tₕₑₐₜ_{_}₂ may be between −20° C., inclusive, and 10° C., inclusive. In one example, the first heating temperature set point Tₕₑₐₜ_{_}₁ may be set at approximately 10° C. and the second heating temperature set point Tₕₑₐₜ_{_}₂ may be set at approximately 5° C. Such a pair of heating temperature set points may be used as part of process 700 at blocks 740 and 750 of FIG. 10 or process 80 at blocks 860 and 870 of FIG. 11.

In yet another implementation, the pair of heating temperature set points Tₕₑₐₜ_{_}₁ and Tₕₑₐₜ_{_}₂, may be used to incrementally increase the heating provided by the first portion 610 of each of the one or more thermoelectric modules 600. For example, in one configuration, when the received temperature T is below the first heating temperature set point Tₕₑₐₜ_{_}₁ then the thermal controller 510 may activate the one or more fans 410 and the one or more thermoelectric modules 600 to heat the interior of the display enclosure 10. The thermal controller 510 may be configured to control the current flowing through the one or more thermoelectric modules 600 using pulse width modulation (PWM). The duty cycle for the pulse width modulation may be determined based on the received temperature T relative to the first and second heating temperature set points Tₕₑₐₜ_{_}₁ and Tₕₑₐₜ_{_}₂. For example, the first and second heating temperature set points Tₕₑₐₜ_{_}₁ and Tₕₑₐₜ_{_}₂ may be between −20° C., inclusive, and 10° C., inclusive. In one example, the first heating temperature set point Tₕₑₐₜ_{_}₁ may be set at approximately 10° C. and the second heating temperature set point Tₕₑₐₜ_{_}₂ may be set at approximately 5° C. In one example, the duty cycle for the pulse width modulation may be determined by

$$DutyCycle = ( \frac{{T}_{heat\_ 1} - T}{{T}_{heat\_ 1} - {T}_{heat\_ 2}} ) \times 100 \% .$$

Thus, the thermal controller 510 may increase the duty cycle of the pulse width modulation provided to control the thermoelectric module 600, and therefore the heating effect provided, based on the temperature T detected by the temperature sensor 560 relative to the heating temperature set points. Of course it should be understood that the heating temperature set points are merely examples and other heating temperature set points may be used. Such a pair of heating temperature set points and control of the thermoelectric modules 600 via pulse width modulation duty cycle may be used as part of process 700 at blocks 740 and 750 of FIG. 10 or process 80 at blocks 860 and 870 of FIG. 11.

The foregoing description of embodiments of the present invention have been presented for purposes of illustration and description. It is not intended to be exhaustive or to limit the present invention to the precise form disclosed, and modifications and variations are possible in light of the above teachings or may be acquired from practice of the present invention. The embodiments were chosen and described to explain the principles of the present invention and its practical application to enable one skilled in the art to utilize the present invention in various embodiments and with various modifications as are suited to the particular use contemplated.

What is claimed is:

1. A display enclosure with a temperature control system comprising:
a display enclosure having an interior, the interior of the display enclosure sized and configured to receive a display device therein;
a thermoelectric module having a first portion and a second portion, the first portion positioned within the interior of the display enclosure, and the second portion coupled to a portion of the display enclosure exposed to an external environment; and
a thermal controller electrically coupled to the thermoelectric module and operable to control heating or cooling of the first portion of the thermoelectric module.

2. The display enclosure of claim 1, wherein the thermoelectric module comprises a Peltier thermoelectric module.

3. The display enclosure of claim 1 further comprising a temperature sensor positioned within the interior of the display enclosure, wherein the temperature sensor is electrically coupled to the thermal controller,
wherein the thermal controller is operable to receive a first signal indicative of a temperature of the interior of the display enclosure output from the temperature sensor, wherein the thermal controller is operable to control the heating or cooling of the first portion of the thermoelectric module based, at least in part, on the first signal output from the temperature sensor.

4. The display enclosure of claim 3 further comprising a humidity sensor positioned within the interior of the display enclosure, wherein the humidity sensor is electrically coupled to the thermal controller,
wherein the thermal controller is further operable to receive a second signal indicative of a humidity of the interior of the display enclosure output from the humidity sensor, and wherein the thermal controller is operable control the heating or cooling of the first portion of the thermoelectric module based, at least in part, on the first signal output from the temperature sensor and the second signal output from the humidity sensor.

5. The display enclosure of claim 3 further comprising an H-Bridge, the H-Bridge electrically coupled to the thermal controller and the thermoelectric module,
wherein the thermal controller is operable to control a direction of current through the thermoelectric module via the H-Bridge.

6. The display enclosure of claim 5, wherein the thermal controller is operable to cause the direction of current through the thermoelectric module to flow in a first direction when the first signal output from the temperature sensor and received by the thermal controller is indicative of a temperature above a first temperature set point.

7. The display enclosure of claim 6, wherein the thermoelectric module is configured to cool the first portion of the thermoelectric module when the direction of current through the thermoelectric module flows in the first direction.

8. The display enclosure of claim 6, wherein the thermal controller is operable to cause the direction of current through the thermoelectric module to flow in a second direction when the first signal output from the temperature sensor and received by the thermal controller is indicative of a temperature below a second temperature set point.

9. The display enclosure of claim 8, wherein the thermoelectric module is configured to heat the first portion of the thermoelectric module when the direction of current through the thermoelectric module flows in the second direction.

10. The display enclosure of claim 1 further comprising a fan disposed within the interior of the display enclosure, the fan electrically coupled to the thermal controller, wherein the thermal controller is further operable to selectively activate and deactivate the fan.

11. The display enclosure of claim 1, wherein the portion of the display enclosure exposed to the external environment includes a heat sink.

12. The display enclosure of claim 1, further comprising a display device disposed within the interior of the display enclosure.

13. The display enclosure of claim 1, wherein the thermal controller is operable to control a duty cycle of pulse width modulation to control the heating or cooling of the first portion of the thermoelectric module.

14. A display enclosure with a temperature control system comprising:
a display enclosure having an interior, the interior of the display enclosure sized and configured to receive a display device therein;
a thermoelectric module having a first portion and a second portion, the first portion positioned within the interior of the display enclosure, the second portion coupled to a portion of the display enclosure exposed to an outdoor environment;
a temperature sensor positioned within the interior of the display enclosure; and
a thermal controller electrically coupled to the thermoelectric module and the temperature sensor, wherein the thermal controller is operable to receive a first signal indicative of a temperature of the interior of the display enclosure output from the temperature sensor, and wherein the thermal controller is operable to control heating or cooling of the first portion of the thermoelectric module based, at least in part, on the first signal output from the temperature sensor.

15. The display enclosure of claim 14, wherein the thermal controller is operable to cause a direction of current through the thermoelectric module to flow in a first direction when the first signal output from the temperature sensor and received by the thermal controller is indicative of a temperature of the interior of the display enclosure above a first temperature set point, and wherein the thermal controller is operable to cause the direction of current through the thermoelectric module to flow in a second direction when the temperature output from the temperature sensor and received by the thermal controller is indicative of a temperature of the interior of the display enclosure below a second temperature set point.

16. The display enclosure of claim 14 further comprising a fan disposed within the interior of the display enclosure, the fan electrically coupled to the thermal controller,
wherein the thermal controller is further operable to activate and deactivate the fan.

17. The display enclosure of claim 14, wherein the portion of the display enclosure exposed to the outdoor environment includes a heat sink.

18. The display enclosure of claim 14, wherein the thermal controller is operable to control a duty cycle of pulse width modulation to control cooling of the first portion of the thermoelectric module, the thermal controller operable to linearly increase the duty cycle based, at least in part, on the first signal, a first cooling temperature set point, and a second cooling temperature set point.

19. A method for controlling the internal temperature of a display enclosure comprising:
receiving, at a thermal controller of a display enclosure, a first signal indicative of a temperature of an interior of the display enclosure;
determining, using the thermal controller, whether first signal indicative of the temperature of the interior of the display enclosure is above a first temperature set point;
activating, using the thermal controller, a thermoelectric module to cool the interior of the display enclosure if the first signal indicative of the temperature of the interior of the display enclosure is above the first temperature set point; and
deactivating, using the thermal controller, the thermoelectric module when the first signal indicative of the temperature of the interior of the display enclosure is below the first temperature set point.

20. The method of claim 19 further comprising:
receiving, at the thermal controller, a second signal indicative of a humidity of the interior of the display enclosure; and
deactivating, using the thermal controller, the thermoelectric module if the second signal indicative of the humidity of the interior of the display enclosure is above a maximum humidity.

21. An enclosure system with a temperature control system comprising:
an enclosure having an interior;
a device housed within the enclosure;
a thermoelectric module having a first portion and a second portion, the first portion positioned within the interior of the enclosure, the second portion coupled to a portion of the enclosure exposed to an external environment; and
a thermal controller electrically coupled to the thermoelectric module and configured to apply an electric current to the thermoelectric module in a first direction and a second direction,
wherein when the electric current is applied by the thermal controller to the thermoelectric module in the first direction, the first portion of the thermoelectric module is cooled and the second portion of the thermoelectric module is heated, and wherein when the electric current is applied by the thermal controller to the thermoelectric module in the second direction, the first portion of the thermoelectric module is heated and the second portion of the thermoelectric module is cooled.

22. A temperature control system, comprising:
a thermoelectric module configured to be operatively connected to an enclosure and including a first portion and a second portion operatively connected to the first portion, the first portion configured to be positioned within the interior of the enclosure, the second portion configured to be exposed to an external environment;
a thermal controller electrically coupled to the thermoelectric module and configured to apply an electric current to the thermoelectric module in a first direction and a second direction,
wherein when the electric current is applied by the thermal controller to the thermoelectric module in the first direction, the first portion of the thermoelectric module is cooled and the second portion of the thermoelectric module is heated, and wherein when the electric current is applied by the thermal controller to the thermoelectric module in the second direction, the first portion of the thermoelectric module is heated and the second portion of the thermoelectric module is cooled.
